(19) United States
(12) Patent Application Publication
(10) Pub. No.: US 2017/0085251 A1
(43) Pub. Date: Mar. 23, 2017

(54) PREAMPLIFIER

(71) Applicant: uPI Semiconductor Corp., Hsinchu County (TW)

(72) Inventor: Wen-Sheng Lin, Hsinchu County (TW)

(21) Appl. No.: 15/083,297

(22) Filed: Mar. 29, 2016

(30) Foreign Application Priority Data
Sep. 17, 2015 (TW) 104130707

(51) Int. Cl. H03H 19/00; H03F 3/387

(52) U.S. Cl. CPC H03H 19/004; H03F 3/387; H03F 2200/271

(57) ABSTRACT

A preamplifier including a programmable gain amplifying circuit and a filtering circuit is provided. The programmable gain amplifying circuit has a single output terminal. The filtering circuit includes a first switched-capacitor filter and a second switched-capacitor filter. The first switched-capacitor filter is coupled to the single output terminal. The second switched-capacitor filter is connected in parallel with the first switched-capacitor filter. The first switched-capacitor filter and the second switched-capacitor filter are respectively switched between a first mode and a second mode. When the first switched-capacitor filter is switched to the first mode, the second switched-capacitor filter is switched to the second mode.

### CROSS-REFERENCE TO RELATED APPLICATION

This application claims the priority benefit of Taiwan application serial no. 104130707, filed on Sep. 17, 2015. The entirety of the above-mentioned patent application is hereby incorporated by reference herein and made a part of this specification.

### BACKGROUND OF THE INVENTION

Field of the Invention

The invention relates to a preamplifier and more particularly relates to a preamplifier with a filtering circuit.

Description of Related Art

An analog front end (AFE) is composed of an analog circuit and a digital and analog mixed circuit and is in charge of performing many operations, such as signal acquisition, analog filtering, and so on. The preamplifier in the analog front end plays an important role in signal acquisition and it usually determines the resolution and signal-to-noise ratio of the system. Generally, the preamplifier amplifies a differential input signal through a chopper amplifier and filters the higher harmonics caused by the input offset voltage of the chopper amplifier through a filtering circuit.

However, the filtering circuits in the existing preamplifiers are mostly formed by one single capacitor. In addition, the capacitor that forms the filtering circuit needs to be very large so as to filter the higher harmonic caused by the input offset voltage. As a result, the hardware costs of the preamplifier increase and miniaturization of the preamplifier is limited.

### SUMMARY OF THE INVENTION

The invention provides a preamplifier that utilizes a switched-capacitor filter to form a filtering circuit, so as to reduce hardware costs of the preamplifier and help to achieve miniaturization of the preamplifier.

The preamplifier of the invention includes a programmable gain amplifying circuit and a filtering circuit. The programmable gain amplifying circuit has a single output terminal. The filtering circuit includes a first switched-capacitor filter and a second switched-capacitor filter. The first switched-capacitor filter is coupled to the single output terminal. The second switched-capacitor filter is connected in parallel with the first switched-capacitor filter. The first switched-capacitor filter and the second switched-capacitor filter are respectively switched between a first mode and a second mode. When the first switched-capacitor filter is switched to the first mode, the second switched-capacitor filter is switched to the second mode.

Based on the above, the preamplifier of the invention utilizes the first switched-capacitor filter and the second switched-capacitor filter to form the filtering circuit, and the first switched-capacitor filter and the second switched-capacitor filter are connected in parallel and have the same circuit structure. In terms of switching of the operation modes, the switching sequence of the first switched-capacitor filter is opposite to the switching sequence of the second switched-capacitor filter. The filtering circuit formed by the first switched-capacitor filter and the second switched-capacitor filter is conducive to reducing the hardware costs of the preamplifier and achieving miniaturization of the preamplifier.

To make the aforementioned more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a circuit diagram of a preamplifier according to an embodiment of the invention.

FIG. 2 is a timing diagram for explaining the preamplifier according to an embodiment of the invention.

FIG. 3 is a circuit diagram of a chopper amplifier according to an embodiment of the invention.

### DESCRIPTION OF THE EMBODIMENTS

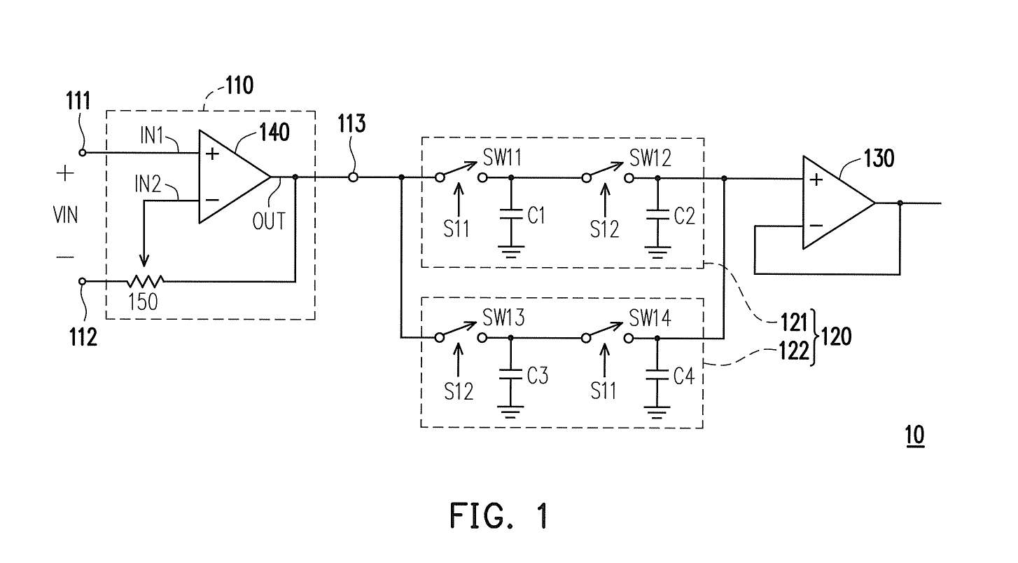

FIG. 1 is a circuit diagram of a preamplifier according to an embodiment of the invention. As shown in FIG. 1, a preamplifier 10 includes a programmable gain amplifying circuit 110 and a filtering circuit 120. The programmable gain amplifying circuit 110 has a single output terminal 113. The filtering circuit 120 includes a first switched-capacitor filter 121 and a second switched-capacitor filter 122. The first switched-capacitor filter 121 is coupled to the single output terminal 113 of the programmable gain amplifying circuit 110. The first switched-capacitor filter 121 is connected in parallel with the second switched-capacitor filter 122.

The first switched-capacitor filter 121 and the second switched-capacitor filter 122 have the same first mode and second mode, and each of the first switched-capacitor filter 121 and the second switched-capacitor filter 122 is switched between the first mode and the second mode. In terms of operation, when the first switched-capacitor filter 121 is switched to the first mode, the second switched-capacitor filter 122 is switched to the second mode. When the first switched-capacitor filter 121 is switched to the second mode, the second switched-capacitor filter 122 is switched to the first mode.

Thereby, an attenuation slope of the filtering circuit 120 in a stopband may reach −40 dB/decade, so as to effectively filter a harmonic component, e.g. a higher harmonic caused by an input offset voltage, in an output signal of the programmable gain amplifying circuit 110. In addition, because the filtering circuit 120 is formed by the first switched-capacitor filter 121 and the second switched-capacitor filter 122, a cutoff frequency of the filtering circuit 120 is determined by a ratio of a plurality of capacitors in the first switched-capacitor filter 121 and the second switched-capacitor filter 122. In other words, the preamplifier 10 may adjust the ratio of the plurality of capacitors to adjust the cutoff frequency of the filtering circuit 120, thereby reducing the layout area of the filtering circuit 120. Accordingly, the hardware costs of the preamplifier 10 can be reduced and miniaturization of the preamplifier 10 can be achieved.

Furthermore, the first switched-capacitor filter 121 and the second switched-capacitor filter 122 have the same circuit structure. Namely, the first switched-capacitor filter 121 includes a first switch SW11, a first capacitor C1, a second switch SW12, and a second capacitor C2. A first terminal of the first switch SW11 is coupled to the single output terminal 113 of the programmable gain amplifying circuit 110. The first capacitor C1 is coupled between a second terminal of the first switch SW11 and a ground. A first terminal of the second switch SW12 is coupled to the second terminal of the first switch SW11. The second capacitor C2 is coupled between a second terminal of the second switch SW12 and the ground. Moreover, in the first mode, the first switch SW11 is turned on while the second switch SW12 is turned off. In the second mode, the first switch SW11 is turned off while the second switch SW12 is turned on.

Similarly, the second switched-capacitor filter 122 includes a third switch SW13, a third capacitor C3, a fourth switch SW14, and a fourth capacitor C4. A first terminal of the third switch SW13 is coupled to the first terminal of the first switch SW11. The third capacitor C3 is coupled between a second terminal of the third switch SW13 and the ground. A first terminal of the fourth switch SW14 is coupled to the second terminal of the third switch SW13. The fourth capacitor C4 is coupled between a second terminal of the fourth switch SW14 and the ground. Moreover, in the first mode, the third switch SW13 is turned on while the fourth switch SW14 is turned off. In the second mode, the third switch SW13 is turned off while the fourth switch SW14 is turned on.

In other words, the first switched-capacitor filter 121 includes the first switch SW11 and the second switch SW12 that are connected in series. The first switch SW11 is coupled to the ground through the first capacitor C1, and the second switch SW12 is coupled to the ground through the second capacitor C2. Similarly, the second switched-capacitor filter 122 includes the third switch SW13 and the fourth switch SW14 that are connected in series. The third switch SW13 is coupled to the ground through the third capacitor C3, and the fourth switch SW14 is coupled to the round through the fourth capacitor C4.

It should be noted that the cutoff frequency of the filtering circuit 120 is proportional to the ratio of the first capacitor C1 and the second capacitor C2 and the ratio of the third capacitor C3 and the fourth capacitor C4. In other words, the cutoff frequency of the filtering circuit 120 may be adjusted by adjusting the ratio of two capacitors. Since the cutoff frequency of the filtering circuit 120 is proportional to the ratio of the two capacitors, the cutoff frequency of the filtering circuit 120 remains unchanged when the capacitance values of the two capacitors are reduced proportionally. Therefore, the layout area of the filtering circuit 120 can be reduced to achieve miniaturization of the preamplifier 10.

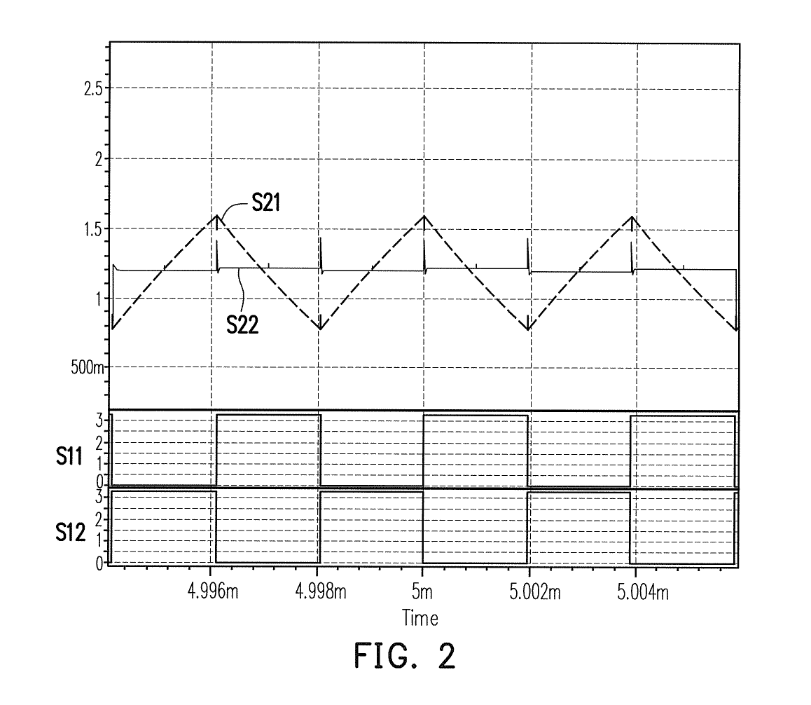

Further, FIG. 2 is a timing diagram for explaining the preamplifier according to an embodiment of the invention. As shown in FIG. 1 and FIG. 2, in the first switched-capacitor filter 121, the first switch SW11 is controlled by a first control signal S11 and the second switch SW12 is controlled by a second control signal S12. The first control signal S11 and the second control signal S12 are two non-overlapping signals, so as to switch the first switched-capacitor filter 121 between the first mode and the second mode.

In terms of switching of the operation modes, a switching sequence of the second switched-capacitor filter 122 is opposite to a switching sequence of the first switched-capacitor filter 121. Thus, the third switch SW13 is controlled by the second control signal S12 and the fourth switch SW14 is controlled by the first control signal S11. When the first switched-capacitor filter 121 is switched to the first mode, the second switched-capacitor filter 122 is switched to the second mode. That is, when the first switch SW11 is turned on and the second switch SW12 is turned off, the third switch SW13 is turned off and the fourth switch SW14 is turned on.

On the other hand, when the first switched-capacitor filter 121 is switched to the second mode, the second switched-capacitor filter 122 is switched to the first mode. That is, when the first switch SW11 is turned off and the second switch SW12 is turned on, the third switch SW13 is turned on and the fourth switch SW14 is turned off. Because the first switched-capacitor filter 121 and the second switched-capacitor filter 122 are connected in parallel and their switching sequences of the operation modes are opposite to each other, the filtering circuit 120 achieves a favorable filtering effect. For example, in FIG. 2, the curve S21 indicates the output signal generated by the programmable gain amplifying circuit 110 in response to the differential input signal VIN, and the curve S22 indicates the signal outputted by the filtering circuit 120. As shown by the curves S21 and S22 of FIG. 2, the filtering circuit 120 effectively filters the harmonic component in the output signal of the programmable gain amplifying circuit 110, so as to generate an amplified DC signal.

With reference to FIG. 1 again, the programmable gain amplifying circuit 110 includes a chopper amplifier 140 and a variable resistor 150. A non-inverting input terminal IN1 of the chopper amplifier 140 forms a first input terminal 111 of the programmable gain amplifying circuit 110, and an output terminal OUT of the chopper amplifier 140 forms the single output terminal 113 of the programmable gain amplifying circuit 110. A first terminal of the variable resistor 150 forms a second input terminal 112 of the programmable gain amplifying circuit 110, a second terminal of the variable resistor 150 is coupled to an inverting input terminal IN2 of the chopper amplifier 140, and a third terminal of the variable resistor 150 is coupled to the output terminal OUT of the chopper amplifier 140 (i.e. the single output terminal 113 of the programmable gain amplifying circuit 110). Thereby, the chopper amplifier 140 forms a negative feedback configuration through the variable resistor 150, such that the programmable gain amplifying circuit 110 may amplify the differential input signal VIN through the chopper amplifier 140 having the negative feedback configuration. The programmable gain amplifying circuit 110 may adjust the variable resistor 150 to adjust a preset gain for amplifying the differential input signal VIN.

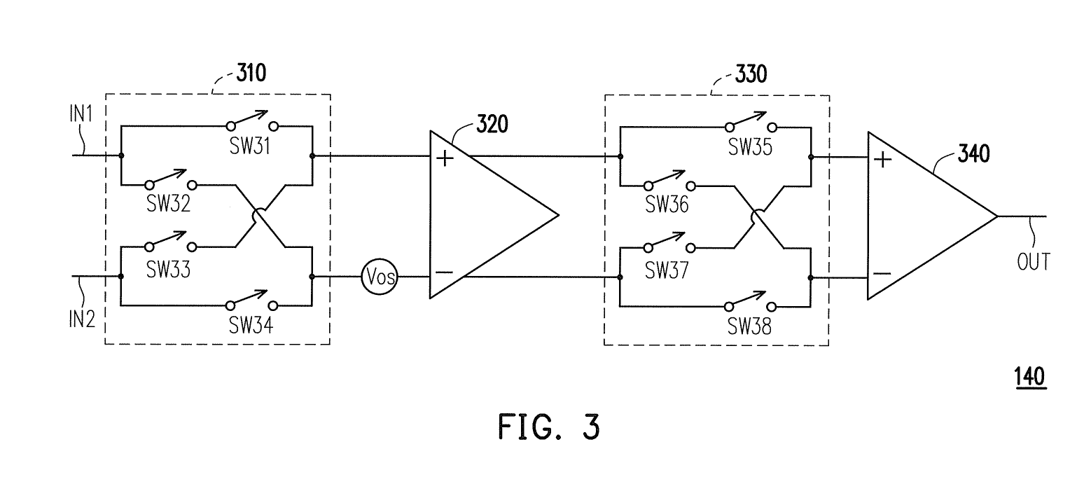

To make the invention more comprehensible to those skilled in the art, FIG. 3 is a circuit diagram of a chopper amplifier according to an embodiment of the invention. As shown in FIG. 3, the chopper amplifier 140 includes a first switching unit 310, an input stage 320, a second switching unit 330, and an output stage 340. The input stage 320 and the output stage 340 may be respectively formed by a transconductance amplifier. Two input terminals of the input stage 320 are coupled to the first switching unit 310, and two output terminals of the input stage 320 are coupled to the second switching unit 330. Moreover, two input terminals of the output stage 340 are coupled to the second switching unit 330.

The first switching unit 310 includes switches SW31-SW34. When the switch SW31 and the switch SW34 are turned on, the switch SW32 and the switch SW33 are turned off. When the switch SW31 and the switch SW34 are turned off, the switch SW32 and the switch SW33 are turned on. Through switching of the switches SW31-SW34, the first switching unit 310 forms a modulator. Similarly, the second switching unit 330 includes switches SW35-SW38. In addition, when the switch SW35 and the switch SW38 are turned on, the switch SW36 and the switch SW37 are turned off. When the switch SW35 and the switch SW38 are turned off, the switch SW36 and the switch SW37 are turned on. Thereby, the second switching unit 330 also forms a modulator.

In terms of operation, the first switching unit 310 may modulate the differential input signal VIN, so as to transpose the differential input signal VIN to an odd harmonic of a chopper frequency. The input stage 320 amplifies an input offset voltage Vos and the modulated differential input signal VIN. The second switching unit 330 modulates the offset voltage Vos and modulates the differential input signal VIN again. Through the second modulation performed by the second switching unit 330, the differential input signal VIN is transposed back to the original frequency band. In addition, the chopper amplifier 140 only performs one modulation on the input offset voltage Vos through the second switching unit 330. Thus, the input offset voltage Vos is transposed to the odd harmonic of the chopper frequency. The output stage 340 converts the differential output signal generated by the second switching unit 330 to a single-ended signal to serve as the output signal of the programmable gain amplifying circuit 110. In other words, the programmable gain amplifying circuit 110 may modulate the input offset voltage Vos to a high frequency band through the chopper amplifier 140, and the filtering circuit 120 may filter the high harmonic caused by the input offset voltage Vos.

In an embodiment of the invention, the preamplifier 10 further includes an operational amplifier 130. A non-inverting input ten al of the operational amplifier 130 is coupled to the filtering circuit 120, and an inverting input terminal of the operational amplifier 130 is electrically connected to an output terminal of the operational amplifier 130. The operational amplifier 130 may serve as a buffer. Accordingly, the preamplifier 10 may output the signal through the buffer formed by the operational amplifier 130, thereby preventing the output voltage from being affected by the back-end load.

In conclusion, the preamplifier of the invention utilizes the first and second switched-capacitor filters that have the same circuit structure to form the filtering circuit, and the first and second switched-capacitor filters are connected in parallel. In terms of switching of the operation modes, the switching sequence of the first switched-capacitor filter is opposite to the switching sequence of the second switched-capacitor filter. Thus, the filtering circuit achieves a favorable filtering effect. In addition, the filtering circuit formed by the first and second switched-capacitor filters is conducive to reducing the hardware costs of the preamplifier and achieving miniaturization of the preamplifier.

It will be apparent to those skilled in the art that various modifications and variations can be made to the disclosed embodiments without departing from the scope or spirit of the invention. In view of the foregoing, it is intended that the invention covers modifications and variations of this disclosure provided that they fall within the scope of the following claims and their equivalents.

What is claimed is:

1. A preamplifier, comprising:
a programmable gain amplifying circuit, comprising a single output terminal; and
a filtering circuit comprising:
a first switched-capacitor filter, coupled to the single output terminal; and
a second switched-capacitor filter, connected in parallel with the first switched-capacitor filter,
wherein the first switched-capacitor filter and the second switched-capacitor filter are respectively switched between a first mode and a second mode, and when the first switched-capacitor filter is switched to the first mode, the second switched-capacitor filter is switched to the second mode.

2. The preamplifier according to claim 1, wherein the first switched-capacitor filter comprises:
a first switch, comprising a first terminal coupled to the single output terminal;
a first capacitor, coupled between a second terminal of the first switch and a ground;
a second switch, comprising a first terminal coupled to the second terminal of the first switch; and
a second capacitor, coupled between a second terminal of the second switch and the ground,
wherein the first switch is turned on and the second switch is turned off in the first mode, and the first switch is turned off and the second switch is turned on in the second mode.

3. The preamplifier according to claim 2, wherein the first switched-capacitor filter and the second switched-capacitor filter have the same circuit structure.

4. The preamplifier according to claim 1, wherein the first switched-capacitor filter comprises a first switch and a second switch that are connected in series, the second switched-capacitor filter comprises a third switch and a fourth switch that are connected in series, and the first switch and the third switch are directly coupled to the single output terminal of the programmable gain amplifying circuit, wherein the third switch is turned off and the fourth switch is turned on when the first switch is turned on and the second switch is turned off, and the third switch is turned on and the fourth switch is turned off when the first switch is turned off and the second switch is turned on.

5. The preamplifier according to claim 4, wherein the first switched-capacitor filter further comprises a first capacitor and a second capacitor, the first switch is coupled to a ground through the first capacitor, and the second switch is coupled to the ground through the second capacitor.

6. The preamplifier according to claim 4, wherein the second switched-capacitor filter further comprises a third capacitor and a fourth capacitor, the third switch is coupled to a ground through the third capacitor, and the fourth switch is coupled to the ground through the fourth capacitor.

7. The preamplifier according to claim 1, wherein the programmable gain amplifying circuit comprises:
a chopper amplifier, comprising a non-inverting input terminal, which forms a first input terminal of the programmable gain amplifying circuit, and an output terminal, which forms the single output terminal; and
a variable resistor, comprising a first terminal, which forms a second input terminal of the programmable gain amplifying circuit, a second terminal, which is coupled to an inverting input terminal of the chopper amplifier, and a third terminal, which is coupled to the single output terminal.

8. The preamplifier according to claim 7, wherein the chopper amplifier comprises:
a first switching unit, modulating a differential input signal received by the chopper amplifier;
an input stage, coupled to the first switching unit and amplifying the modulated differential input signal and an input offset voltage;
a second switching unit, coupled to the input stage, and the second switching unit modulating the input offset voltage and modulating the differential input signal again to generate a differential output signal; and
an output stage, converting the differential output signal to a single-ended signal.

9. The preamplifier according to claim 1, further comprising:
an operational amplifier, comprising a non-inverting input terminal, which is coupled to the filtering circuit, and an output terminal and an inverting input terminal of the operational amplifier are coupled to each other.
